(19) United States
(12) Patent Application Publication
(10) Pub. No.: US 2023/0317702 A1
(43) Pub. Date: Oct. 5, 2023

(54) Large-Scale Interleaved Transmitters and Receivers Heterogeneously Integrated on a Common Substrate

(71) Applicant: Fathom Radiant, PBC, Boulder, CO (US)

(72) Inventors: J. Israel Ramirez, Denver, CO (US); Keith Behrman, Boulder, CO (US)

(21) Appl. No.: 18/191,308

(22) Filed: Mar. 28, 2023

Related U.S. Application Data
(60) Provisional application No. 63/326,399, filed on Apr. 1, 2022.
(60) Provisional application No. 63/327,682, filed on Apr. 5, 2022.
(60) Provisional application No. 63/332,556, filed on Apr. 19, 2022.

(51) Int. Cl. H01L 25/16; H04J 14/02; H01L 23/00; H01L 25/00

(52) U.S. Cl. CPC H01L 25/167; H04J 14/0278; H01L 24/08; H01L 25/50; H01L 2224/08145

(57) ABSTRACT

A large-scale array of interleaved optoelectronic transmitters and receivers are integrated on the surface of a common substrate with integrated circuits. The interleaved configuration allows the optimization of a channel pair.

This application claims the benefit of provisional applications 63/326,399, titled “Large-Scale Interleaved Transmitters and Receivers Heterogeneously Integrated on a Common Substrate” and filed on 1 Apr. 2022; 63/327,682 titled “Apparatus and Methods for Flip-Printing a Plurality of Devices with a Common Contact” and filed on 5 Apr. 2023, and 63/332,556 titled “Methods of Stacking Optoelectronic Wafers” and filed on 19 Apr. 2022; and incorporates all of them herein by reference.

### FIELD OF INVENTION

The invention relates to methods of integrating interleaved optoelectronic devices onto a common substrate to achieve optimal data communication.

### DISCUSSION OF RELATED ART

Optical communication is a lower energy and faster methodology of communicating data across all communication lengths except for very short distances when compared with purely electrical methods through conductive medium. Two-way optical communication typically involves a transmitter (TX) and a receiver (RX) to send and receive optical signals through a transmission medium. A single transmitter and receiver can send information in only one direction. For fully bidirectional communication, a transmitter and receiver pair may exist at each node in a single channel pair.

Electronic devices that are able to convert electrical signals to optical and vice-versa, also known as transmitters and/or receivers, herein also called transceivers, can be fabricated from various semiconductor materials. Semiconductors can be broadly classified as direct bandgap or indirect bandgap materials. Other, novel materials also exist such as zero-band gap materials (1D or 2D materials) or organic semiconductors but for simplicity will not be discussed. Direct band-gap materials are generally preferred over indirect band-gap for their higher efficiency in electron-to-photon conversion. In addition, direct band-gap semiconductor carriers tend to have a lower effective mass which translates into higher electron/hole velocities. This makes these materials attractive for high-speed applications such as optical communication. At the same time, these same characteristics make them less suitable for ultra-low power electronics. A combination of materials properties, economics, and materials compatibility has created a fragmented industry where manufacturers focus on either direct-bandgap or indirect-bandgap semiconductor fabrication. Namely, on one hand, there is a well-established semiconductor industry using Silicon, an indirect-bandgap semiconductor, to build ultra-low power electronics known as Si CMOS integrated circuits. On the other hand, there is a mature, but comparatively smaller, manufacturing industry that focuses on fabrication of direct-bandgap semiconductors such as GaAs and other III-V materials. Given the incompatibility, in terms of cross-contamination, of III-V-based materials and Silicon, these two are not volume manufactured at the same facilities. Heterogeneous integration of Silicon and III-V-based materials is a common method to bring those two material systems together.

As the need for higher baud rate increases to keep up with computationally intensive algorithms, the use of simply Si CMOS as drivers and copper wires as the transmission medium becomes more challenging. Increasing the distance between nodes at ISO-power is not possible due to the losses in the medium (copper wires). These high baud rates are needed for emerging applications where physically disaggregated systems are preferably connected as if they were tightly aggregated. The use of optical transceivers instead of copper wire allows communication to break the paradigm of increasing power at the expense of high baud rate and/or increased distance between nodes. This has been exploited by the use of pluggable optical transceivers in high traffic applications such as data centers and telecommunications. However, the explosion of data traffic demands and increased needs for higher baud rates, Silicon integrated circuits, including application-specific ICs ASICs, and optical transceivers can benefit from being closer together to continue reducing the energy per bit at a ISO-cost.

FIG. 1 (prior art) shows a common substrate 100 such as Silicon CMOS, also referred as backplane or IC or ASIC, or a glass substrate with integrated thin-film electronics, or any other resistive substrate material with patterned integrated circuits on it. The top image is a plan view and the bottom image is a side view. 200 and 250 are optoelectronic materials that are patterned to form an array of transmitters and receivers, respectively. These devices have an electrical connection to a Silicon backplane for electro-optical conversion. This connection is typically done by wire-bonding, mass-transfer printing or die-to-substrate bonding using techniques such as thermo-compression bonding, eutectic bonding, or direct-bonding. Most die-to-substrate bonding is typically front-to-front connection between the backplane and the die. This process is also known as flip-chip bonding. For flip-chip, the transceivers operate within a favorable wavelength that is transparent to its own substrate or the substrate is removed. Given the transmitters and receivers are on separate substrates, the minimum distance between a transmitter and receiver is set by the number of opto-electronic elements multiplied by the pitch of transceiver to transceiver.

FIG. 2 (prior art) shows a typical common substrate 100 with metal pads 245 that direct-connect to arrayed transmitters 200 and receivers 250 via electrical pads 240. The connection is typically done via wire bonds 241. State-of-the-art wire-bonds need a minimum pad size of 20×20 um. In order to enable high bandwidth per mm², it is preferable to use other integration methods that allow for higher packaging density of opto-electronics onto a silicon substrate.

### SUMMARY

Interleaved optoelectronic transmitters and receivers are integrated on the surface of a common substrate with integrated circuits. The interleaved configuration allows the optimization of a channel pair. Architecture and methods in which Silicon CMOS backplane and optical transceivers are integrated optimize for high speed, low energy, and cost to enable data communication across multi-nodes systems.

Apparatus includes an electronic backplane and a large-scale interleaved array of optical transmitters and optical receivers heterogeneously integrated to the electronic backplane. They may be interleaved in a checkerboard pattern. The transmitters and receivers can be individually electrically modulated. Two of these apparatuses may be linked to form a communications system.

The optical transmitters and optical receivers are configured to operate at multiple wavelengths. A spatial multiplexer or a wavelength multiplexer may be attached in order to multiplex optical signals emitted from the large-scale interleaved array.

The optical transmitters and optical receivers within the large-scale interleaved array may be fabricated from silicon photonic semiconductors, compound semiconductors, 2D semiconductor materials, organic semiconductor materials, or thin film materials.

The optical transmitters and optical receivers may be integrated via mass-transfer printing. For example, the mass-transfer printing can be accomplished via more than one transfer and configured to connect the optical transmitters and optical receivers front-to-front to a CMOS backplane.

The integration may be accomplished via thermo-compression bonding, eutectic bonding, or direct bonding.

The optical transmitters and optical receivers can be fabricated on a single substrate and connected to a CMOS backplane. A through-substrate via can be added. Three or more substrates may be stacked and connected to an electronic backplane.

### BRIEF DESCRIPTION OF DRAWINGS

FIG. 1 (Prior art) is a schematic diagram showing a common substrate with arrayed optoelectronic transmitters and receivers connected to the substrate.

FIG. 2 (Prior art) is a schematic plan view showing a common substrate with optoelectronic transmitters and receivers connected to the substrate using wire bonds.

FIG. 3A is a schematic plan view showing an apparatus consisting of a common substrate with interleaved optoelectronic transmitters and receivers.

FIG. 3B is a system level depiction of an exemplary connection of ICs and transceiver arrays via an optical connection.

FIG. 4A is a schematic diagram showing a common substrate with bond pads.

FIG. 4B is a schematic diagram showing a common substrate with optoelectronic transmitters and receivers connected to the substrate using lithographically patterned metal wires.

FIG. 4C is a schematic diagram showing a temporary substrate used to pick up optoelectronics to transfer them onto a common substrate.

FIG. 4D is a schematic diagram showing a common substrate with arrayed transceivers connected to the common substrate via lithographically defined wires with respective insulators to prevent short circuits.

FIG. 5A is a schematic diagram showing a common substrate with bond pads.

FIG. 5B is a schematic diagram showing patterned optoelectronics transceivers on their grown substrate.

FIG. 5C is a schematic diagram showing optoelectronics transceivers on a temporary substrate.

FIG. 5D is a schematic diagram showing optoelectronics transceivers on both a primary (front side) and second temporary substrate (back side).

FIG. 5E is a schematic diagram showing optoelectronics transceivers on a second temporary substrate with its contacts aligned and connected to the contacts of the common substrate front-to-front.

FIG. 5F is a schematic diagram showing two types of optoelectronics transceivers aligned and connected to a common substrate.

FIG. 6A is a schematic diagram showing two types of optoelectronics transceivers grown sequentially on one substrate.

FIG. 6B is a schematic diagram showing the optoelectronics transceivers aligned and connected to a common substrate.

FIG. 7A is a schematic diagram showing a common substrate with bond pads.

FIG. 7B is a schematic diagram showing patterned optoelectronics transceivers on a substrate.

FIG. 7C is a schematic diagram showing patterned optoelectronics transceivers on a substrate with a through substrate via.

FIG. 7D is a schematic diagram showing the optoelectronics transceivers aligned and connected to a common substrate.

FIG. 8A is a schematic diagram showing two types of optoelectronics transceivers grown sequentially on one substrate.

FIG. 8B is a schematic diagram showing a common substrate with bond pads.

FIG. 8C is a schematic diagram showing the optoelectronics transceivers aligned and connected to a common substrate with an optical window.

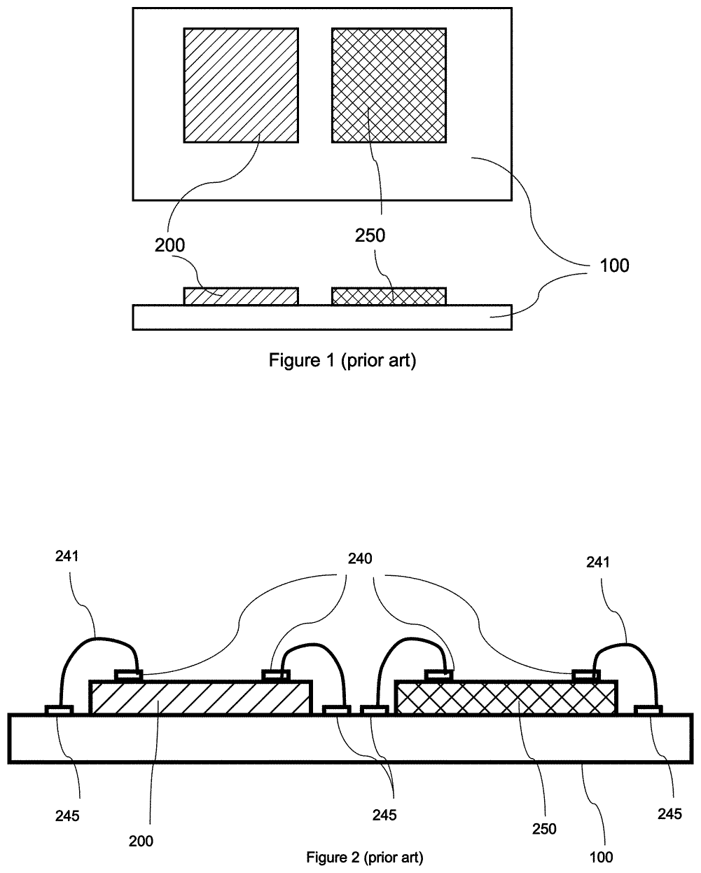

### DETAILED DESCRIPTION OF THE INVENTION

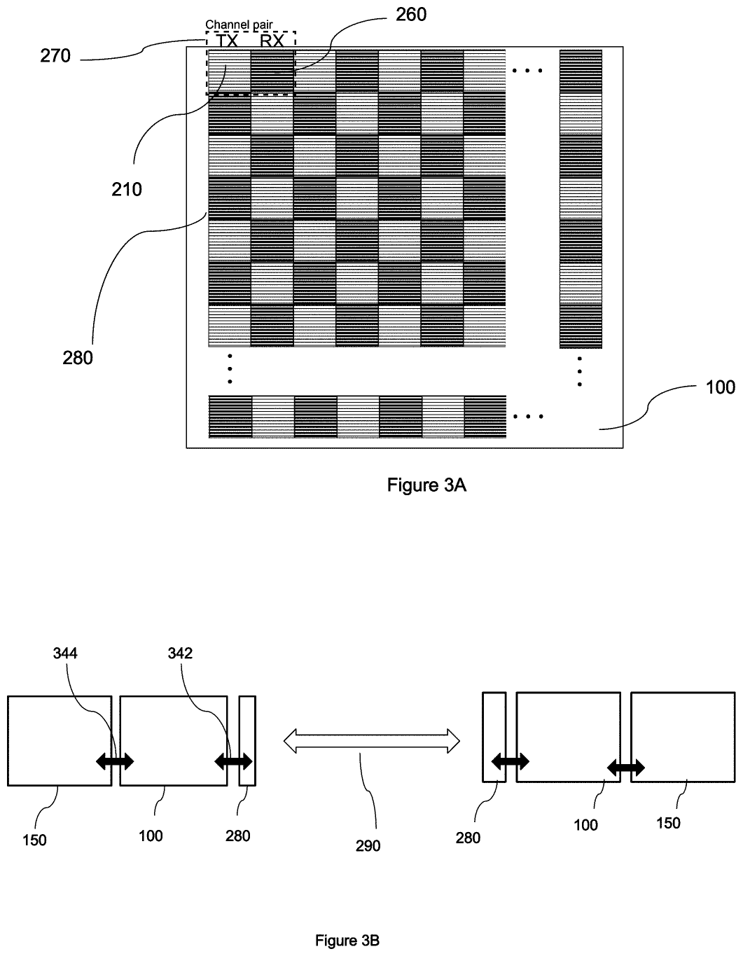

FIG. 3A show a common substrate 100 with large-scale interleaved optoelectronic transmitters 210 and receivers 260 heterogeneously integrated on the common substrate 100, in this case forming a checkerboard pattern. In this embodiment, a device array consisting of numerous light-emitting transmitters/emitters 210 (i.e VCSEL, LED) and photodetector receivers 260 are directly integrated onto a Silicon CMOS backplane 100. Both the emitters and receivers may have multi-wavelength operation.

For example, VCSEL 210 and photodetector 260 pair represent a bi-directional channel 270 and 280 is the array of channel pairs. These bi-directional channels 270 may be used in different multiplex modalities such as space division or wavelength-division. The total data rate can then be calculated by multiplying the speed of a transceiver channel element 270 by the number of elements in array 280. It is then advantageous to match the transceiver count to the desired all-to-all system bandwidth. A large-scale array may range from 10 s of optoelectronic elements to 1000's elements. In one example, the number of elements is a minimum of 256 and as many as 1024 to target bandwidths >1 Tb/s

FIG. 3B shows a block level of an exemplary implementation of this apparatus into a system, wherein the channel pairs 280 are connected 342 to backplane 100 to transfer data and the backplane 100 may also be connected 344 to application-specific integrated circuits (ASICs) 150 where computation or data traffic control may be handled. The optical channel pairs 280 connection 290 to other nodes may be via free-space, optical elements or optical fiber (not shown).

The transceiver count is limited by the area available for the individual opto-electronic elements 210, 260 on the underlying substrate 100. Each device 210, 260 is on the order of 5 to 500 μm long on a side with a similar device-to-device pitch.

FIG. 3A shows a square grid of equal sized transmitters 210 and receivers 260; however, the opto-electronic devices could be arranged in any array form with periodic or non-uniform spacing. Each channel pair 270 (TX and RX) can perform bidirectional communication with a complementary channel pair located at a different node separated by a communication medium. Utilizing high speed VCSELs and photodetectors enables each channel pair to have >1G of bidirectional bandwidth.

For applications where data is generated locally, interleaving the signal channel pairs 270 minimizes the distance that data needs to move electronically. However, densely interleaving the channel pairs 270 poses an integration and packaging challenge as the transmitters 210 and receivers 260 are typically formed in separate manufacturing processes.

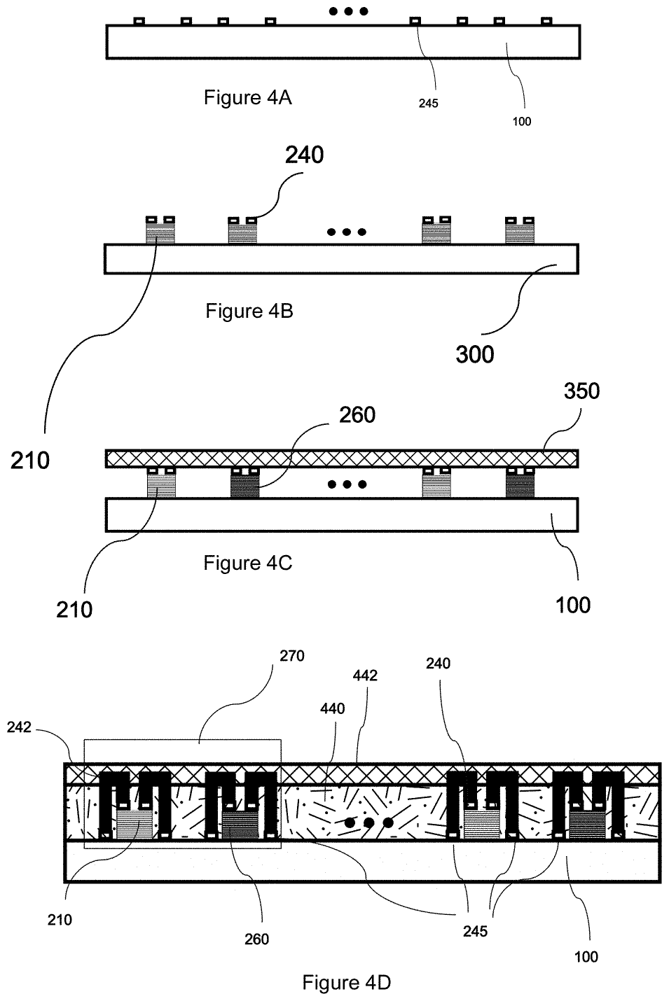

In an example embodiment of FIG. 4A, a silicon logic wafer 100 is fabricated in a complementary metal-oxide-semiconductor (CMOS) process with bond pads 245 that correspond to the driver circuitry (not shown) for a transmitter 210 and bond pads 245 that correspond to the circuitry (not shown) to connect the receiver 260. In FIG. 4B, GaAs-based light emitting devices 210 are fabricated on a chosen substrate 300, metallized electrical pads 240 are formed, and devices 210 are singulated. The active semiconductor layers (not shown) that comprise the optoelectronic transmitters 210 are now ready to be lifted-off from the substrate 300. Possible release methods of the optoelectronic transmitters 210 are by targeting a layer/interface by means of chemical, mechanical or high-energy sources such as temperature or laser. In one embodiment, an interface with a specific chemical concentration is etched via chemistry but a focused wavelength can also be used to absorb at a particular interface. Following this, a second GaAs photodetector receiver 260 is transferred for each RX channel 270 using the same method described above.

In FIG. 4C, a temporary substrate 350 is used as a carrier for each type of released optoelectronic transceivers 210, 260 to populate the common substrate 100. Options for a temporary substrate 350 can be materials with tackness or magnetic materials coupled with an external electric field. FIG. 4D shows optoelectronic transceivers 210, 260 transferred to the CMOS wafer 100 via mass-transfer printing for all transmitter (TX) channels 210. With all transceivers transferred, an encapsulation or protection dielectric layer 440 can be applied before patterning metal wires 242 from both optoelectronic devices to their respective CMOS bond pads 245. Finally, an optional encapsulation or protection dielectric layer 442 is applied to protect the wiring. The use of lithographically patterned metal wires 242 enables narrow lines which helps parasitics and allows for high packing density. This method is scalable to wafer scale, so cycle time is minimized. A person skilled in the art to which the invention pertains understands that the transceivers may operate at more than one wavelength.

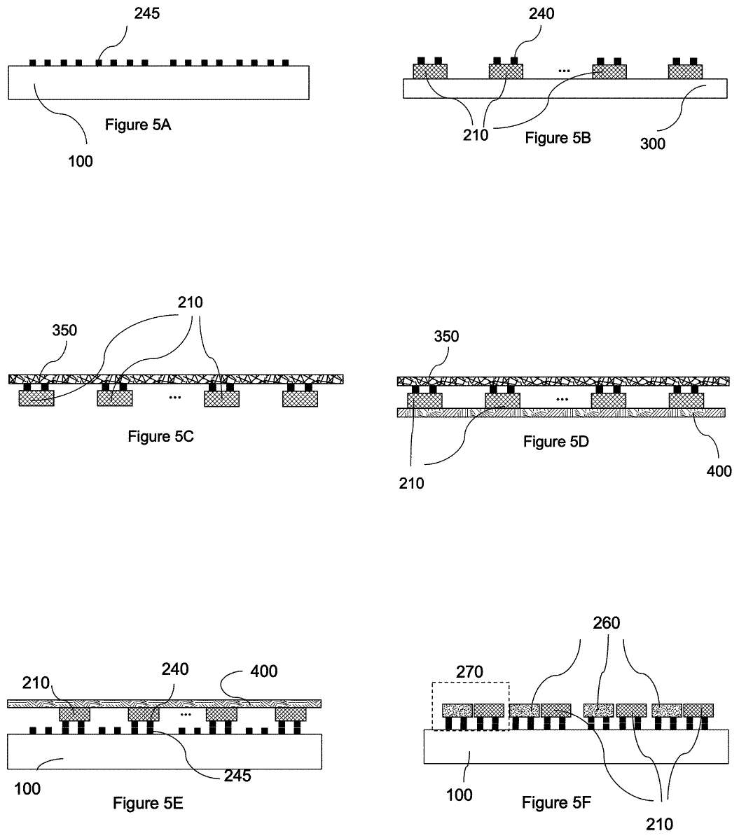

Another example embodiment is shown in FIGS. 5A-5F. In FIG. 5A, a silicon logic wafer 100 is fabricated in a complementary metal-oxide-semiconductor (CMOS) process with bond pads 245 that correspond to the electronic circuitry needed to drive the transceivers described next. FIG. 5B shows GaAs-based light-emitting optoelectronic devices 210 fabricated and singulated on a chosen substrate 300. Additionally, contacts 240 are formed at the top of the singulated devices 210 with a conductive layer that matches the size and pitch of the contacts to the silicon substrate. The contact 240 may have a conductive layer that protrudes above the substrate to readily make physical contact to the incoming chips. An embodiment of the conductive layer 240 can be an under-bump-metallization (UBM) like Ni/Au with a soft metal like Indium.

The active semiconductor layers that comprise the optoelectronic devices 210 are now ready to be lifted-off from the substrate 300. Possible release methods of the optoelectronic devices 210 are by targeting a layer/interface by means of chemical, mechanical or high-energy sources such as temperature or laser. In one embodiment, an interface with a specific chemical concentration is etched via chemistry but a focused wavelength can also be used to absorb at a particular interface. In FIG. 5C, a temporary substrate 350 is used as a carrier for the released optoelectronic devices 210. Options for a temporary substrate 350 can be materials with tackness or magnetic materials coupled with an external electric field. FIG. 5D, a second temporary substrate 400 is brought into contact with the backside of the optoelectronic devices 210. This enables the optoelectronics to connect front-to-front to a backplane 100. The temporary bonding strength of substrate 400 needs to be greater than substrate 350. This ensures optoelectronic devices 210 are transferred to substrate 400. Increasing the bonding strength of substrate 400, compared to substrate 300 can be achieved by chemical or photo-chemical surface modification or by simply choosing a different material system.

In FIG. 5E, the temporary substrate 400 with arrayed optoelectronic devices 210 and the optoelectronic device contacts 240 are aligned to the silicon CMOS wafer 100 contacts 245 and brought into physical contact. The process shown in FIGS. 5B through 5E are repeated for receivers 260, so that receivers 210 and transmitters 210 are interleaved as shown in FIG. 5F. Steps in FIG. 5B-5E can be repeated for as many optoelectronic transmitters 210 and receivers 260 types as desired.

FIG. 5F shows a populated silicon backplane 100 with transmitters 210 and receivers 260 pairs 270. In the embodiment described here, by bringing the conductive layers face-to-face, the wiring length is reduced, resulting in reduced RC parasitics. The packing density of the optoelectronics pairs 270 can be maximized over the backplane 100 because there is no additional wiring needed.

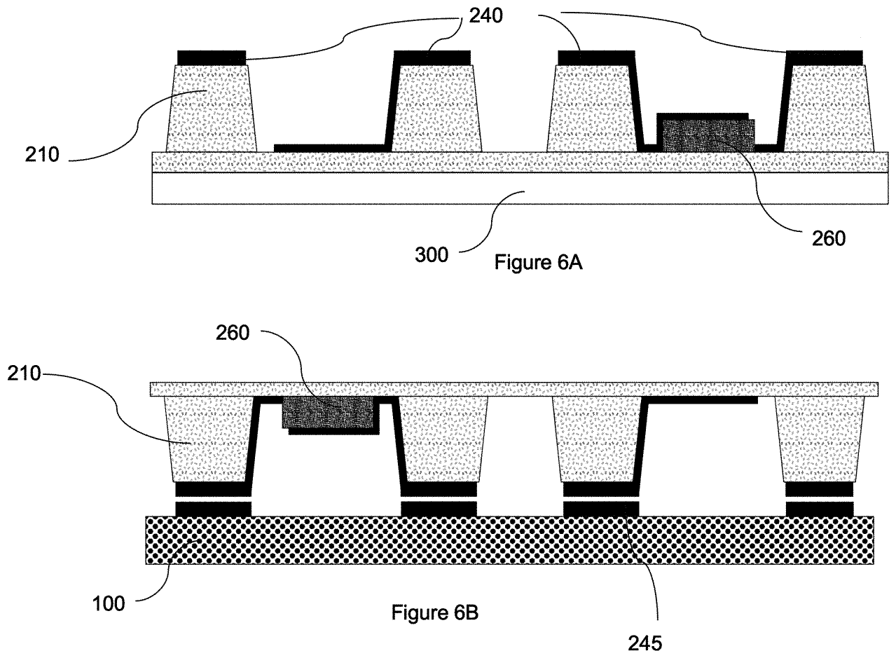

In another example embodiment, FIG. 6A, an optoelectronic transmitter 210 is fabricated and singulated on a chosen substrate 300. For example an optoelectronic transmitter 210 may be made from GaAs that emits light. Next, a patternable and vacuum-deposited thin-film material stack from a different optoelectronic material (such as amorphous silicon), compared to the formed 210 device, is formed as a stacked secondary device structure to form a receiver 260.

It is possible to take advantage of singulated mesas not used as transmitters for the metal contacts of the emitter to be brought to the same height as the rest of the pads 240. Here, in FIG. 6A, a metal contact 240 coats the structure sidewall and may be electrically isolated by an insulating material (not shown). The receiver 260 thin-film device is built in the field area where transmitters 210 are not present to allow incident light to be absorbed at the thin-film device rather than interact with the transmitter optoelectronic device 210. For packaging, this structure can be integrated in a top-emission format through wire bond, thermal compression, or similar interconnects. Alternatively, The device is ready for flip-chip packaging as shown in FIG. 6B where the optoelectronics stack can be integrated directly with a CMOS backplane 100 with pitch-matched contacts 245 for electrical control. The substrate 300 where the optoelectronics were fabricated may be removed (as shown here) if it is beneficial to improve optical efficiency for given wavelengths.

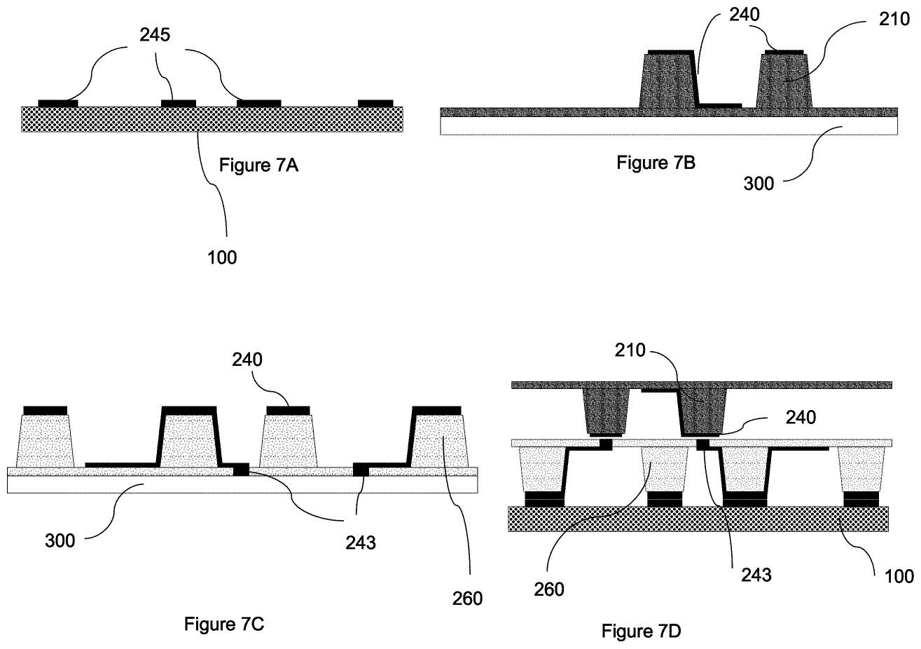

In another example embodiment, shown in FIGS. 7A-7D, a silicon logic wafer 100 is fabricated in a complementary metal-oxide-semiconductor (CMOS) process with bond pads 245 that correspond to the electronic circuitry (not shown) to connect the transmitters 210 and receivers 260. Next, two different optoelectronic transceivers are fabricated on separate wafers through their respective epitaxy, growth, or semiconductor processing methods. In FIG. 7B, optoelectronics are made from III-V-based material to be used as transmitters 210. FIG. 7C, optoelectronics made from III-V-based material to be used as receivers 260. The receivers 260 are fabricated with conductive through-substrate vias 243. FIG. 7B shows the fabricated transmitters 210 with contact pads 240 that are pitch matched to correspond with the receivers 260 of FIG. 7C through-substrate vias 243. FIG. 7D shows the CMOS backplane 100 in electrical contact with the aligned receivers 210. The emitters' 260 contact pads 240 are aligned to the receivers' 210 through-substrate vias 243 to electrically connect the receivers 260 to the CMOS backplane 100.

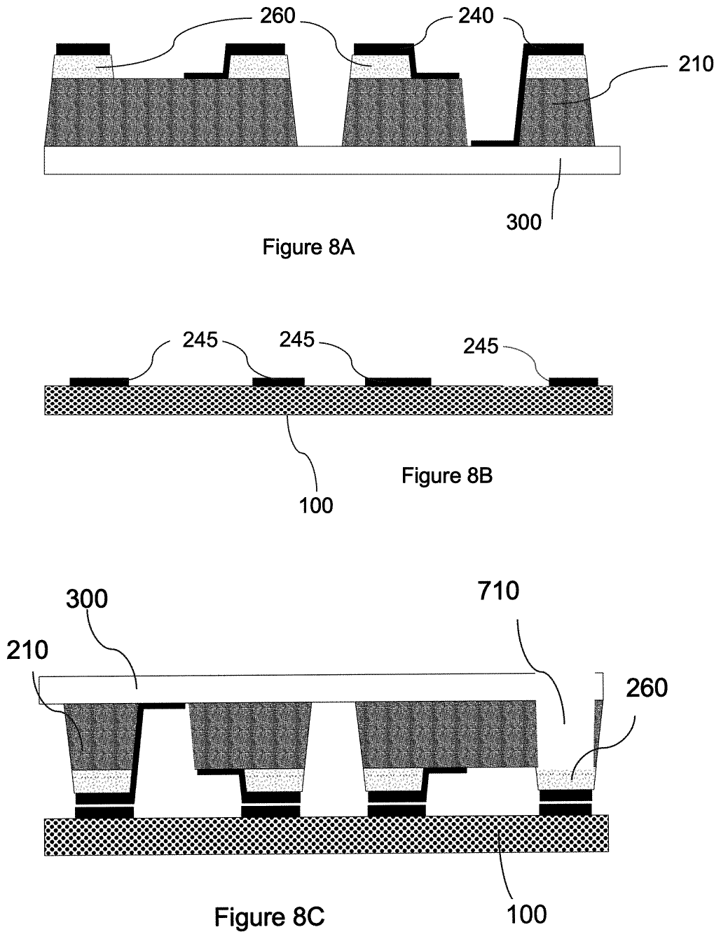

In another embodiment shown in FIGS. 8A-8C, two different epitaxial device structures, that correspond to transmitters 210, and receivers 260 are grown in series on the same substrate 300. Both layers are lattice compatible materials. In FIG. 8A, the first grown structure is a semiconductor device used for emitters 210 and the second grown structure is used for the receivers 260. The emitters 210 and receivers 260 are isolated and electrical pads 240 are formed. In FIG. 8B, a silicon logic wafer 100 is fabricated in a complementary metal-oxide-semiconductor (CMOS) process with bond pads 245 that correspond to the circuitry for transmitters 210 and respective bond pads 245 that correspond to the circuitry (not shown) to connect the receivers 260.

Next, the substrate 300 with the fabricated emitters 210 and receivers 260 in FIG. 8A is aligned and connected to the CMOS backplane 100 contacts 245 in FIG. 8B. In FIG. 8C, a lithographic step is performed to remove the emitter layers 210 wherever a receiver 260 device exists including parts of the substrate 300. This optical window 710 allows incident light to reach the receivers without being absorbed or reflected by the emitter epitaxial layers.

Those skilled in the art will appreciate that the examples herein may be modified in various ways within the spirit of the invention. For example, where transmitters are formed first and receivers are formed second, the order of these operations may be reversed such that receivers are formed first and transmitters are formed second. Or, processes and steps may be combined from the various embodiments. In the embodiments we focus on up to 3 layers of stacking but multiple stacking of optoelectronics is also possible. The interleaved checkerboard pattern is arbitrary for the transmitter pair; other patterns like alternating rows, or alternating columns are possible. The transmitter pairs may be composed of different materials compositions to operate at different wavelengths with respect to adjacent transmitter pairs. Also, other materials beyond Silicon CMOS and GaAs may be used such as indium-gallium-zinc-oxide, organic semiconductors, chalcogenide materials, among others.

What is claimed is:

1. Apparatus comprising:
a first electronic backplane; and
a first large-scale interleaved array of optical transmitters and optical receivers heterogeneously integrated to the first electronic backplane.

2. The apparatus of claim 1 wherein the first large-scale interleaved array forms a checkerboard pattern.

3. The apparatus of claim 1, wherein the first interleaved array comprises individually electrically modulated optical emitters and optical receivers.

4. The apparatus of claim 1, further comprising:
a second large-scale interleaved array of optical transmitters and optical receivers heterogeneously integrated to a second electronic backplane;
wherein the first interleaved array is linked to the second interleaved array and configured to form a communications system.

5. The apparatus of claim 1 wherein optical transmitters and optical receivers within the first interleaved array are configured to operate at multiple wavelengths.

6. The apparatus of claim 1, further comprising a spatial multiplexer adjacent to the first interleaved array and configured to spatially multiplex optical signals emitted from the large-scale interleaved array.

7. The apparatus of claim 1, further comprising a wavelength multiplexer adjacent to the first interleaved array and configured to wavelength multiplex optical signals emitted from the large-scale interleaved array.

8. The apparatus of claim 1, wherein optical transmitters and optical receivers within the first interleaved array are fabricated from silicon photonic semiconductors.

9. The apparatus of claim 1, wherein optical transmitters and optical receivers within the first interleaved array are fabricated from compound semiconductors.

10. The apparatus of claim 1, wherein optical transmitters and optical receivers within the first interleaved array are fabricated from 2D semiconductor materials.

11. The apparatus of claim 1 wherein optical transmitters and optical receivers within the first interleaved array array are fabricated from organic semiconductor materials.

12. The apparatus of claim 1, wherein optical transmitters and optical receivers within the first interleaved array are fabricated from thin film materials.

13. The apparatus of claim 1, wherein optical transmitters and optical receivers within the first interleaved array are integrated via mass-transfer printing.

14. The apparatus of claim 13, wherein the mass-transfer printing is accomplished via more than one transfer and configured to connect optical transmitters and optical receivers within the first interleaved array front-to-front to a CMOS backplane.

16. The apparatus of claim 1, integrated via thermo-compression bonding.

17. The apparatus of claim 1, integrated via eutectic bonding.

18. The apparatus of claim 1, integrated via direct bonding.

19. The apparatus of claim 1, wherein optical transmitters and optical receivers within the first interleaved array are fabricated on a single substrate and connected to a CMOS backplane.

20. The apparatus of claim 19, further comprising a through-substrate via.

21. The apparatus of claim 1, further comprising at least three substrates stacked and connected to the first electronic backplane.

22. A method comprising:
providing an electronic backplane;
heterogeneously integrating a large-scale array of optical transmitters on the electronic backplane;
heterogeneously integrating a large-scale array of optical receivers on the electronic backplane, interleaving the optical receivers with the optical transmitters.
